(19) United States
(12) Patent Application Publication
(10) Pub. No.: US 2026/0249419 A1
(43) Pub. Date: Aug. 27, 2026

(54) SUBSTRATE PROCESSING DEVICE AND SUBSTRATE PROCESSING METHOD

(71) Applicant: EBARA CORPORATION, Tokyo (JP)

(72) Inventors: Masayuki TAMURA, Tokyo (JP); Takahiro HIGA, Tokyo (JP)

(21) Appl. No.: 19/543,103

(22) Filed: Feb. 18, 2026

(30) Foreign Application Priority Data
Feb. 26, 2025 (JP) 2025-029344

(51) Int. Cl. B24B 37/10; B24B 37/04; B24B 37/12; B24B 37/32; B24B 37/34; H10P 52/40

(52) U.S. Cl. CPC B24B 37/105; B24B 37/042; B24B 37/12; B24B 37/32; B24B 37/34; H10P 52/402

(57) ABSTRACT

A substrate processing device includes a top ring, a swing cover fixed to the top ring, a turntable to which a polishing pad is attachable and that rotates the polishing pad, and an atomizer that supplies a washing fluid to the polishing pad, in which when a top ring head is at a transfer position for transferring a substrate, the swing cover is positioned between the substrate and the polishing pad, and when the top ring head is at a polishing position for polishing the substrate with the polishing pad, the swing cover does not overlap the polishing pad in a plan view.

### CROSS-REFERENCE TO RELATED APPLICATION

Priority is claimed on Japanese Patent Application No. 2025-029344, filed on February 26, 2025, the content of which is incorporated herein by reference.

### BACKGROUND OF THE INVENTION

### Field of the Invention

The present invention relates to a substrate processing device and a substrate processing method.

### Description of Related Art

Japanese Unexamined Patent Application, First Publication No. 2024-131363 discloses a configuration for preventing a polishing liquid from adhering to a rotating body such as a polishing head or the like in a substrate processing device that performs chemical mechanical polishing (CMP) or the like.

In a CMP apparatus or the like, a polishing liquid (slurry) or the like may be scattered from a rotating polishing pad due to centrifugal force and may adhere to a substrate in standby.

The present invention has been made in consideration of such circumstances, and an object of the present invention is to provide a substrate processing device and a substrate processing method capable of suppressing adhesion of scattered matter from a polishing pad to a substrate in standby.

### SUMMARY OF THE INVENTION

In order to solve the above problems, a substrate processing device according to an aspect 1 of the present invention includes: a top ring including a top ring head that holds a substrate and configured to swing; a swing cover fixed to the top ring; a turntable to which a polishing pad is attachable and configured to rotate the polishing pad; and an atomizer configured to supply a washing fluid to the polishing pad, in which when the top ring head is at a transfer position for transferring the substrate, the swing cover is positioned between the substrate and the polishing pad, and when the top ring head is at a polishing position for polishing the substrate with the polishing pad, the swing cover does not overlap the polishing pad in a plan view.

According to an aspect 2 of the present invention, the substrate processing device according to the aspect 1 further includes a fixed cover fixed at a position between the substrate and the polishing pad in a plan view, and the fixed cover and the swing cover are located at different positions in a vertical direction.

According to an aspect 3 of the present invention, the substrate processing device according to the aspect 1 or 2, the swing cover is bent or curved in a plan view.

According to an aspect 4 of the present invention, the substrate processing device according to any one of the aspects 1 to 3 further includes at least one cover washing nozzle configured to jet a cover washing liquid onto the swing cover.

According to an aspect 5 of the present invention, the substrate processing device according to any one of the aspects 1 to 3 further includes a first cover washing nozzle and a second cover washing nozzle, the first cover washing nozzle is configured to jet a cover washing liquid onto a first surface of the swing cover facing the top ring head, and the second cover washing nozzle is configured to jet the cover washing liquid onto a second surface of the swing cover opposite to the first surface.

According to an aspect 6 of the present invention, there is provided a substrate processing method using the substrate processing device according to the aspect 4, the substrate processing method including: a polishing step of pressing the substrate against the polishing pad in a state where the turntable is rotated; a moving step of moving the substrate held by the top ring head by swinging the top ring head from the polishing position to the transfer position after the polishing step; a release step of releasing the substrate from the top ring head at the transfer position after the moving step; a top ring washing step of washing the top ring head after the release step; a pad washing step of supplying the washing fluid from the atomizer to the polishing pad and washing the polishing pad; a holding step of holding a substrate different from the substrate by the top ring head after the top ring washing step; and a cover washing step of jetting the cover washing liquid from the cover washing nozzle and washing the swing cover, in which the cover washing step is performed simultaneously with at least one of the release step, the top ring washing step, the pad washing step, and the holding step.

According to the above-described aspects of the present invention, it is possible to suppress the adhesion of scattered matter from the polishing pad to the substrate in standby.

### BRIEF DESCRIPTION OF THE DRAWINGS

FIG. 1 is a plan view showing a schematic configuration of an entire substrate processing device according to the present embodiment.

FIG. 2 is a perspective view showing a structure around a top ring according to the present embodiment.

FIG. 3 is a view taken in the direction of arrow III in FIG. 2.

FIG. 4 is a plan view showing a case where the top ring is at a polishing position in a substrate polishing device according to the present embodiment.

FIG. 5 is a plan view showing a state where the top ring of FIG. 4 is moved to a transfer position.

FIG. 6 is a perspective view showing a periphery of a swing cover of FIG. 5.

FIG. 7 is a schematic cross-sectional view of the periphery of the swing cover taken along a line VII-VII of FIG. 5.

FIG. 8 is a view showing a modification example of the swing cover of FIG. 3.

FIG. 9 is a view for describing a problem in a configuration in the related art.

### DETAILED DESCRIPTION OF THE INVENTION

Hereinafter, a substrate processing device and a substrate processing method according to the present embodiment will be described with reference to the drawings.

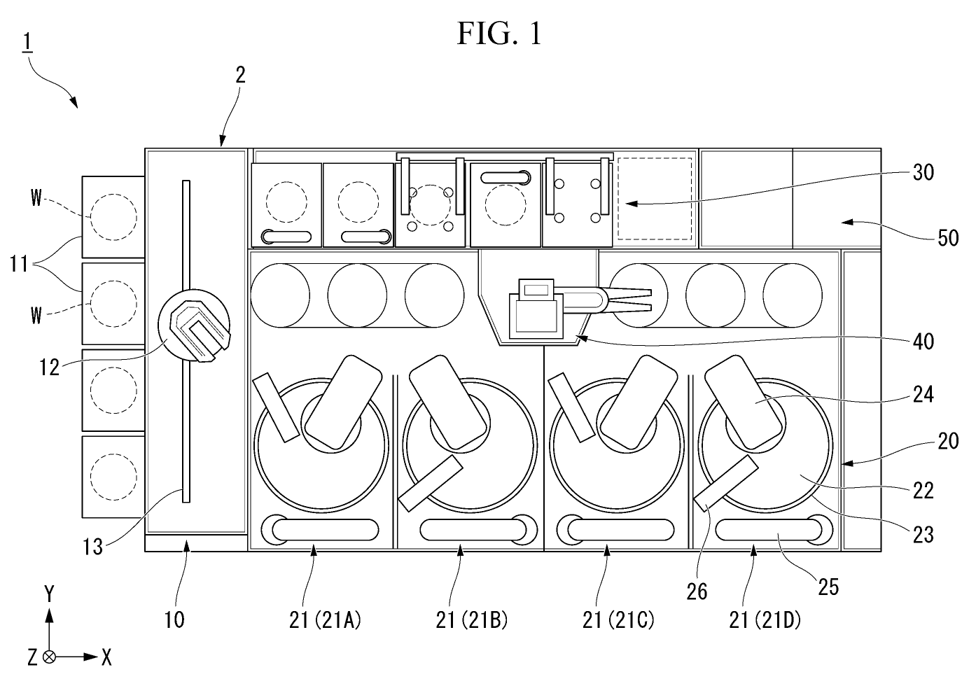

A substrate processing device 1 shown in FIG. 1 is a chemical mechanical polishing (CMP) apparatus that polishes a surface of a substrate W such as a silicon wafer to be flat. The substrate processing device 1 includes a rectangular box-shaped housing 2.

### Direction definition

In FIG. 1 and the like, a Z-axis indicates a vertical direction. An X-axis indicates one direction orthogonal to the Z-axis. A Y-axis indicates one direction orthogonal to both the Z-axis and the X-axis. In the following description, each direction represented by the X, Y, and Z axes may be referred to as the vertical direction Z, a first direction X, and a second direction Y. Viewing from the vertical direction Z is referred to as a plan view. The housing 2 has a substantially rectangular shape in a plan view. An outer shape of the housing 2 has a dimension in the first direction X longer than a dimension in the second direction Y.

As shown in FIG. 1, a substrate processing device 1 includes a load/unload unit 10, a polishing unit 20, a washing unit 30, a substrate transport unit 40, and a control unit 50. The load/unload unit 10 is disposed at an end portion of the housing 2 in the first direction X. The polishing unit 20 and the washing unit 30 are disposed at both end portions of the housing 2 in the second direction Y. The control unit 50 integrally controls operations of the load/unload unit 10, the polishing unit 20, the washing unit 30, and the substrate transport unit 40.

The control unit 50 includes a processor (central processing unit: CPU), a memory, and the like. The memory stores various data and programs. The memory is configured with a volatile memory, a non-volatile memory, a flash memory, and the like. The functions of the control unit 50 are realized by the processor executing a computer program (software) stored in the memory. Some or all of the functions of the control unit 50 may be realized by hardware (including a circuitry) such as a large scale integration (LSI), an application specific integrated circuit (ASIC), a field-programmable gate array (FPGA), or a graphics processing unit (GPU), or may be realized by cooperation between software and hardware.

The load/unload unit 10 includes a plurality of front load units 11. Each front load unit 11 is disposed along an end surface (side surface) of the housing 2 in the second direction Y. The front load unit 11 is equipped with, for example, an open cassette, a standard manufacturing interface (SMIF) pod, or a front opening unified pod (FOUP). The SMIF and the FOUP are sealed containers that store the cassette of the substrate W inside and are covered with a partition wall and can maintain an environment independent of the external space.

The load/unload unit 10 includes a conveyance robot 12 and a traveling mechanism 13. The conveyance robot 12 loads and unloads the substrate W to and from each front load unit 11. The traveling mechanism 13 extends along the second direction Y and moves the conveyance robot 12 in the second direction Y. As a result, the conveyance robot 12 can access the plurality of front load units 11.

The polishing unit 20 includes a plurality of substrate polishing devices 21. The plurality of substrate polishing devices 21 are arranged in the longitudinal direction (first direction X) of a substrate transport path 3. In the example of FIG. 1, the number of the substrate polishing devices 21 is four. These substrate polishing devices 21 have the same configuration as each other. In the following, in a case where the four substrate polishing devices 21 are distinguished and described, reference numerals 21A, 21B, 21C, and 21D are assigned. In a case where the substrate polishing devices 21 are not distinguished, the substrate polishing devices 21 are simply described as “substrate polishing device 21”. The number of the substrate polishing devices 21 included in the polishing unit 20 is not limited to four and can be changed.

The substrate polishing device 21 polishes and flattens the substrate W. Each of the substrate polishing devices 21 includes a polishing pad 22, a turntable 23, a top ring 24, a dresser 25, and an atomizer 26. In addition, although not shown, the substrate polishing device 21 also includes a polishing liquid supply nozzle or the like for supplying a polishing liquid (slurry) or a dressing liquid (for example, pure water) to the polishing pad 22. The polishing pad 22 is a consumable and is attachable to and detachable from the turntable 23. At the time of shipment of the substrate processing device 1, the polishing pad 22 may not be attached to the turntable 23. In addition, the polishing pad 22 may not be attached to the turntable 23 during a period in which the substrate polishing device 21 does not perform polishing work, for example, during inspection, repair, transport of the device, or the like.

The polishing pad 22 has a polishing surface for polishing the substrate W. In the present embodiment, an upper surface of the polishing pad is used as the polishing surface. The polishing pad 22 is attached to an upper end portion of the turntable 23. The turntable 23 is rotated based on control by the control unit 50. As a result, the polishing pad 22 is also rotated. The top ring 24 holds the substrate W and presses the substrate W toward the polishing pad 22. Details of the top ring 24 will be described later.

The substrate polishing device 21 presses the substrate W against the polishing pad 22 with the top ring 24 while supplying a polishing liquid onto the polishing pad 22 and further moves the top ring 24 and the turntable 23 relative to each other. As a result, the substrate polishing device 21 polishes the substrate W to flatten the surface thereof.

The dresser 25 dresses the polishing surface of the polishing pad 22. The dresser 25 has a rotation portion that comes into contact with the polishing pad 22. Hard particles such as diamond particles and ceramic particles are fixed to the rotation portion of the dresser 25. The dresser 25 swings while rotating the rotation portion to uniformly dress the entire polishing surface of the polishing pad 22, thereby forming a flat polishing surface.

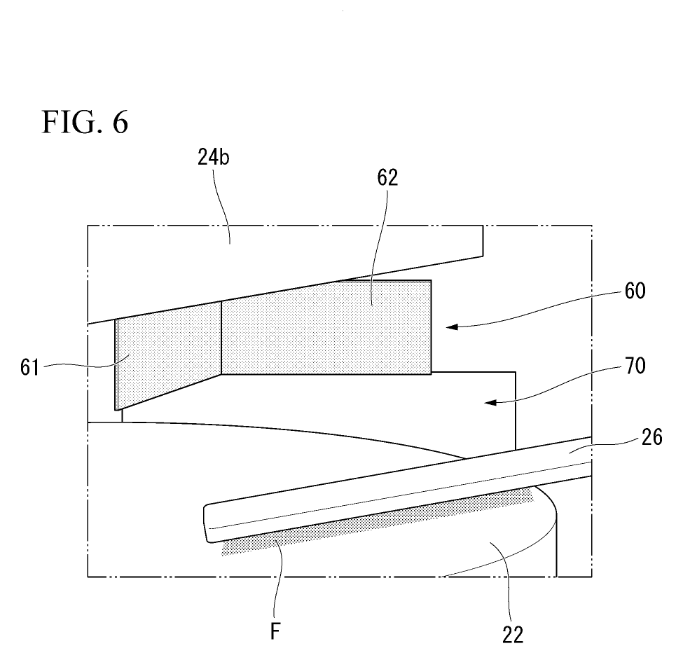

The atomizer 26 jets a washing fluid F (see FIG. 6) onto the polishing surface of the polishing pad 22. The washing fluid F jetted by the atomizer 26 may be a mixed fluid of a liquid (for example, pure water) and a gas (for example, nitrogen gas). Alternatively, the washing fluid F jetted by the atomizer 26 may be a mist of a liquid (for example, pure water). The atomizer 26 jets the washing fluid at a high pressure onto the polishing surface of the polishing pad 22 to wash away polishing debris, abrasive grains, and the like remaining on the polishing surface. As a result, the polishing surface is purified, and the dressing work of the polishing surface by the dresser 25, that is, the regeneration of the polishing surface is achieved.

The substrate transport unit 40 shown in FIG. 1 transfers the substrate W between the load/unload unit 10, the polishing unit 20, and the washing unit 30. The washing unit 30 washes the substrate W polished by the substrate polishing device 21. In addition, the washing unit 30 dries the washed substrate W.

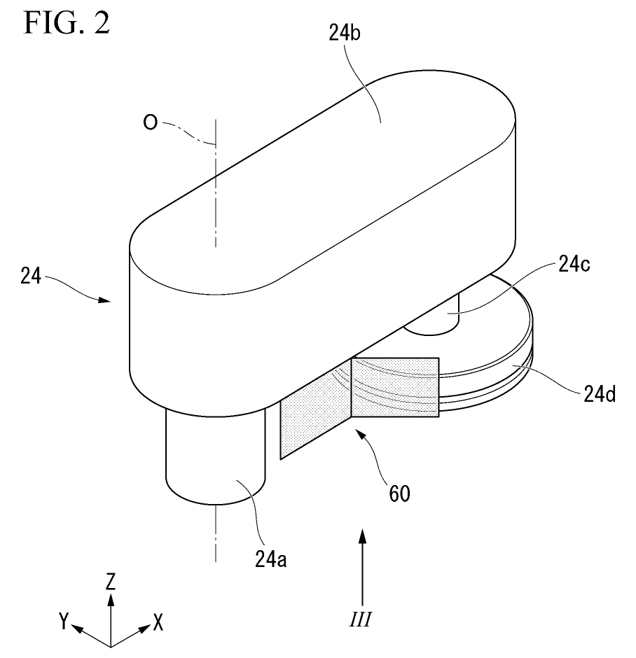

FIG. 2 is a perspective view showing a schematic configuration of the top ring 24. The top ring 24 includes a shaft body 24a, a top ring cover 24b, a lifting and lowering mechanism 24c, and a top ring head 24d. The operation of each part of the top ring 24 described below is controlled by the control unit 50. The shaft body 24a has a central axis O extending in the vertical direction Z. The top ring cover 24b, the lifting and lowering mechanism 24c, and the top ring head 24d are swingable around the central axis O. The shaft body 24a itself may swing, or the top ring head 24d or the like may swing relative to the shaft body 24a without the shaft body 24a swinging.

Inside the top ring cover 24b, a drive unit that drives the lifting and lowering mechanism 24c, a coupling portion that couples the shaft body 24a and the lifting and lowering mechanism 24c, and the like are accommodated. The top ring head 24d is attached to a lower end of the lifting and lowering mechanism 24c. The lifting and lowering mechanism 24c changes the position of the top ring head 24d in the vertical direction Z by lifting and lowering. The top ring head 24d can hold the substrate W. That is, the top ring 24 can swing the substrate W around the central axis O or move the substrate W in the vertical direction Z while holding the substrate W by the top ring head 24d.

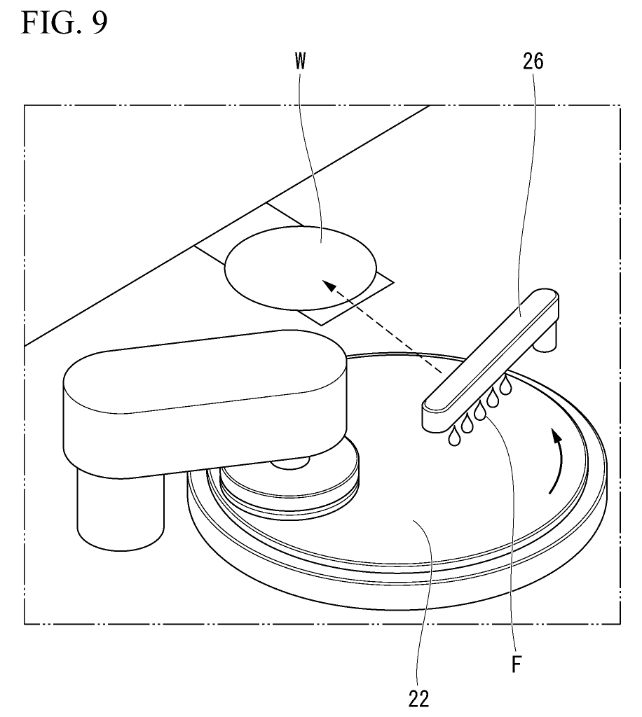

FIG. 9 is a view for describing a problem in a configuration in the related art. FIG. 9 is not a view related to the substrate processing device 1 of the present embodiment. However, since the substrate processing device 1 of the present embodiment is the same as that in the related art in that the atomizer 26 jets the washing fluid F to the polishing pad 22, the same reference numerals are given for convenience of description. The substrate W in FIG. 9 is in a standby state and is disposed at a transfer position when the substrate W is transferred from the top ring 24 to the substrate transport unit 40. When the substrate W is at the transfer position and the polishing pad 22 rotates, for example, the washing fluid F jetted from the atomizer 26 and adhered onto the polishing pad 22 may be scattered by centrifugal force. In addition to the washing fluid F, slurry or the like may be scattered by the centrifugal force. When such scattered matter adheres to the substrate W in a standby state, the treatment process of the substrate W may be adversely affected.

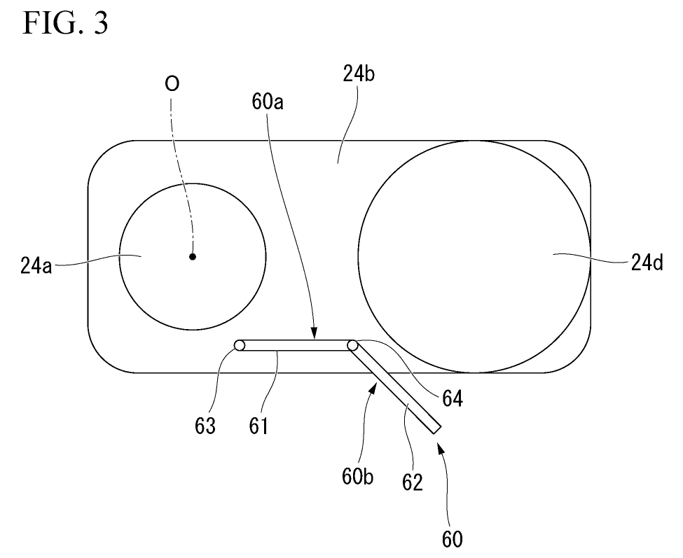

In order to solve the above-described problem, the substrate processing device 1 of the present embodiment includes a swing cover 60 and the like as shown in FIGS. 2 and 3 and the like. FIG. 3 is a view taken in the direction of arrow III in FIG. 2. As shown in FIGS. 2 and 3, the swing cover 60 is attached to the top ring 24. The swing cover 60 has a first surface 60a facing a top ring head 24d side and a second surface 60b on a side opposite to the first surface 60a.

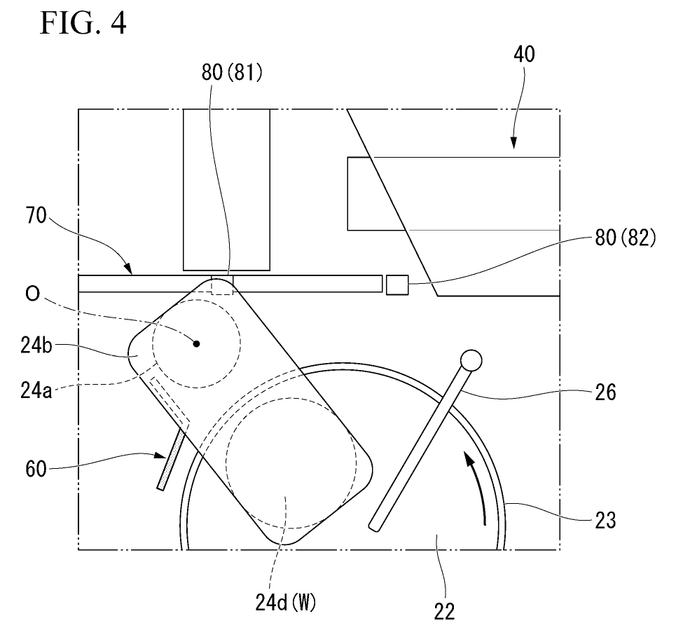

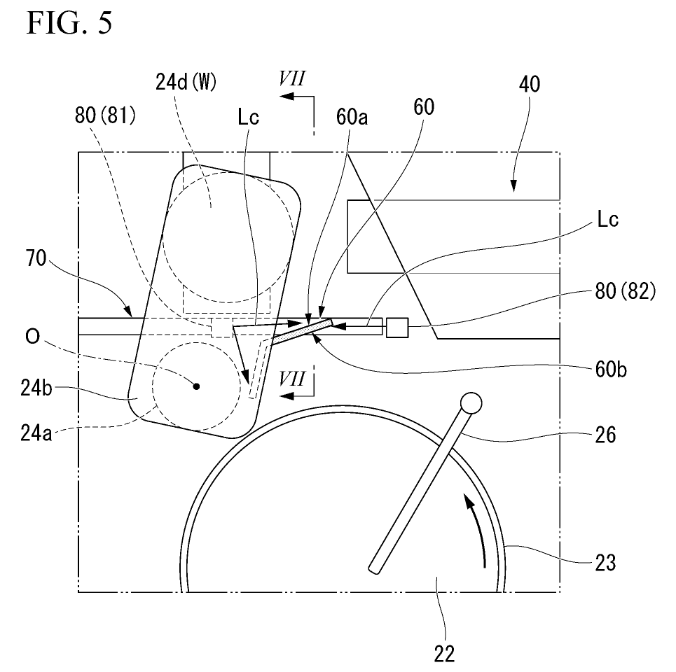

FIGS. 4 and 5 are plan views showing a periphery of the substrate polishing device 21. FIG. 4 shows a case where the top ring head 24d is at a polishing position, and FIG. 5 shows a case where the top ring head 24d is at a transfer position. The top ring 24 swings around a central axis O, so that the top ring head 24d moves between the polishing position (FIG. 4) and the transfer position (FIG. 5). Here, the “polishing position” is a position where the substrate W held by the top ring head 24d is pressed against the polishing pad 22 and polished. When the top ring head 24d is at the polishing position, the top ring head 24d and the substrate W overlap the polishing pad 22 in a plan view. The “transfer position” is a position where the substrate W is transferred from the top ring head 24d to the substrate transport unit 40. When the top ring head 24d is at the transfer position, the top ring head 24d and the substrate W do not overlap the polishing pad 22 and are separated from the polishing pad 22 in a plan view. When the top ring head 24d is at the transfer position (FIG. 5), the second surface 60b of the swing cover 60 faces the polishing pad 22.

As shown in FIGS. 4 and 5, a fixed cover 70 and a cover washing nozzle 80 are disposed in the vicinity of the top ring 24. In the present embodiment, the number of the cover washing nozzles 80 is two, and hereinafter, the cover washing nozzles 80 may be referred to as a first cover washing nozzle 81 and a second cover washing nozzle 82, respectively. However, the number of the cover washing nozzles 80 can be changed. In addition, the cover washing nozzles 80 may not be provided.

In the example of FIG. 3, the swing cover 60 is bent in a plan view and has a first portion 61 and a second portion 62. The first portion 61 is linear in a plan view, and both end portions thereof are fixed to the lower surface of the top ring cover 24b by screws 63 and 64. The second portion 62 is linear in a plan view. A part of the second portion 62 protrudes toward the outside of the top ring cover 24b in a plan view.

As shown in FIG. 5, when the top ring head 24d is at the transfer position, the swing cover 60 is located between the top ring head 24d and the polishing pad 22. Therefore, even when a liquid such as a slurry or the like is scattered from the polishing pad 22 by centrifugal force, the swing cover 60 and the fixed cover 70 can suppress the adhesion of the scattered matter to the substrate W. In addition, since the swing cover 60 is bent, a part of the swing cover 60 (the second portion 62 in the example of FIG. 3) can be brought close to the top ring head 24d. As the distance between the swing cover 60 and the top ring head 24d is smaller, the adhesion of the scattered matter to the substrate W held by the top ring head 24d can be suppressed. In addition, since the swing cover 60 is bent and a part of the swing cover 60 protrudes toward the outside of the top ring cover 24b in a plan view, a space between the polishing pad 22 and the substrate W can be shielded in a wider range.

In addition, when the top ring head 24d is at the transfer position (FIG. 5), a cover washing liquid Lc is jetted from the first cover washing nozzle 81 and the second cover washing nozzle 82. The cover washing liquid Lc is a liquid for washing the swing cover 60, and is, for example, pure water. The first cover washing nozzle 81 is disposed at a position where the first surface 60a of the swing cover 60 can be washed. The second cover washing nozzle 82 is disposed at a position where the second surface 60b of the swing cover 60 can be washed. Since the swing cover 60 is bent, the cover washing liquid Lc jetted from the second cover washing nozzle 82 can be caused to flow along the second surface 60b while the splashing back of the cover washing liquid Lc from the second surface 60b is suppressed, and a wide range of the second surface 60b can be washed. By suppressing the splashing back of the cover washing liquid Lc, it is possible to prevent the cover washing liquid Lc from adhering to the polishing pad 22.

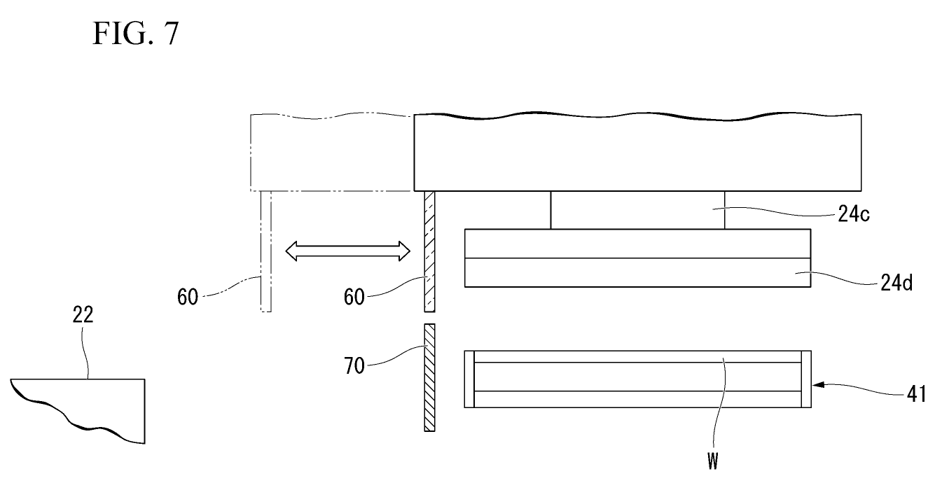

FIG. 6 is a perspective view showing the vicinity of the swing cover 60 in FIG. 5. FIG. 7 is a schematic view for describing a positional relationship between the swing cover 60 and the fixed cover 70. In FIG. 7, the position of the swing cover 60 when the swing cover 60 is at the transfer position (FIG. 5) is indicated by a solid line, and the position of the swing cover 60 when the swing cover 60 is at the polishing position (FIG. 4) is indicated by a broken line.

As shown in FIG. 6, the swing cover 60 and the fixed cover 70 have different positions in the vertical direction Z. Therefore, even in a case where the swing cover 60 and the fixed cover 70 overlap each other in a plan view shown in FIG. 5, the swing cover 60 and the fixed cover 70 do not actually interfere with each other. In other words, when the top ring 24 swings around the central axis O, the swing cover 60 and the fixed cover 70 do not collide with each other.

In addition, as shown in FIG. 7, when the swing cover 60 is at the transfer position (solid line), the swing cover 60 and the fixed cover 70 function as one shielding object and shield a space between the polishing pad 22 and the substrate W. Therefore, it is possible to more reliably prevent scattered matter from the polishing pad 22 from reaching the substrate W. However, even in a case where the fixed cover 70 is not provided, a certain degree of scattering prevention effect can be obtained by the swing cover 60. Therefore, it is not essential to provide the fixed cover 70.

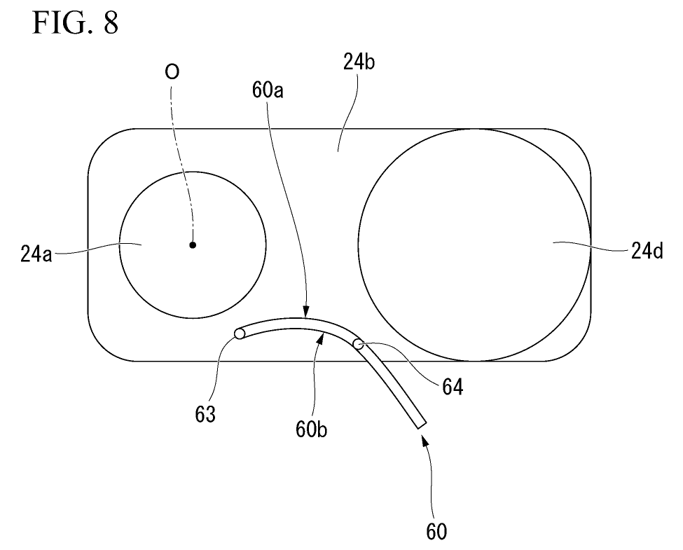

FIG. 8 shows a modification example of the shape of the swing cover 60 in FIG. 3. As shown in FIG. 8, the swing cover 60 may be curved in a plan view. In this case as well, the same effect as in a case where the swing cover 60 is bent can be obtained.

Next, an example of a substrate processing method using the substrate processing device 1 configured as described above will be described. The substrate processing method includes, for example, a polishing step, a moving step, a release step, a pad washing step, a top ring washing step, a holding step, and a cover washing step.

In the polishing step, the substrate W is polished by the polishing pad 22. Specifically, the top ring head 24d is positioned at a polishing position (FIG. 4) in a state where the substrate W is held by the top ring head 24d. Further, the top ring head 24d is lowered by the lifting and lowering mechanism 24c in a state where the turntable 23 is rotated, and the substrate W is pressed against the polishing pad 22 at a predetermined pressure. At this time, a slurry or the like is supplied to the polishing pad 22.

After the completion of the polishing step, the moving step is performed. In the moving step, the top ring head 24d is swung from the polishing position to the transfer position (FIG. 5) while holding the polished substrate W. As a result, the polished substrate W is moved from the polishing position to the transfer position. At this time, the top ring head 24d is moved upward by the lifting and lowering mechanism 24c, and the substrate W is released from the polishing pad 22.

After the moving step, the release step is performed. In the release step, the substrate W is released from the top ring head 24d. For example, in the example of FIG. 7, the substrate W is transferred to the transfer unit 41 located below the top ring head 24d. The substrate W may be washed, dried, or the like while being held by the transfer unit 41. The substrate W after the completion of the washing and drying is moved from the transfer unit 41 by the substrate transport unit 40. In addition, a new substrate W to be polished is set in the transfer unit 41 in preparation for the next polishing step.

After the moving step, the pad washing step is performed. The pad washing step may be performed simultaneously with the release step. In the pad washing step, the washing fluid F is supplied from the atomizer 26 to the polishing pad 22 to wash the polishing pad 22. The polishing pad 22 may be dressed by the dresser 25 before or simultaneously with the pad washing step.

After the release step, the top ring washing step is performed. In the top ring washing step, the top ring head 24d is washed. As a result, the slurry or the like adhering to the top ring head 24d in the polishing step is washed.

After the top ring washing step, the holding step is performed. In the holding step, the substrate W different from the substrate W released in the release step is held by the top ring head 24d. Specifically, the top ring head 24d is lowered toward a new substrate W set in the transfer unit 41, and the substrate W is held by the top ring head 24d. After the holding step, the top ring head 24d swings from the transfer position to the polishing position, and the polishing step and subsequent steps are repeated.

In the cover washing step, the cover washing liquid Lc is jetted from the cover washing nozzle 80 to wash the swing cover 60. In the example of FIG. 5, the first surface 60a of the swing cover 60 is washed by the first cover washing nozzle 81, and the second surface 60b of the swing cover 60 is washed by the second cover washing nozzle 82.

Here, it is preferable that the cover washing step is performed from the start of the release step to the completion of the holding step. That is, it is preferable that the cover washing step is performed simultaneously with at least one of the release step, the top ring washing step, the pad washing step, and the holding step. As a result, in a series of processes, a period in which only the cover washing step is performed is eliminated. Therefore, it is possible to prevent a decrease in the number of substrates W processed per unit time (wafers per hour: WPH). However, in a series of processes, the cover washing step may not be performed, and the cover washing step may be performed, for example, while the substrate processing device 1 is stopped.

As described above, the substrate processing device 1 of the present embodiment includes the top ring 24 including the top ring head 24d that holds the substrate W and configured to swing, the swing cover 60 fixed to the top ring 24, the turntable 23 to which the polishing pad 22 is attachable and configured to rotate the polishing pad 22, and the atomizer 26 configured to supply the washing fluid F to the polishing pad 22. When the top ring head 24d is at the transfer position (FIG. 5) for transferring the substrate W, the swing cover 60 is located between the substrate W and the polishing pad 22. When the top ring head 24d is at the polishing position (FIG. 4) for polishing the substrate W with the polishing pad 22, the swing cover 60 does not overlap the polishing pad 22 in a plan view.

According to the substrate processing device 1, the following effects can be obtained. When the top ring head 24d is at the transfer position (FIG. 5), the swing cover 60 is located between the substrate W and the polishing pad 22. Therefore, the swing cover 60 can prevent the slurry, the washing fluid F, or the like scattered from the rotating polishing pad 22 by the centrifugal force from adhering to the substrate W. In addition, when the top ring head 24d is at the polishing position (FIG. 4), the swing cover 60 does not overlap the polishing pad 22 in a plan view. Therefore, it is possible to prevent the slurry or the like scattered from the polishing pad 22 and adhering to the swing cover 60 from dripping from the swing cover 60 and adversely affecting the polishing process. Further, since the swing cover 60 swings together with the top ring 24, for example, power or control solely for driving the swing cover 60 is not required. As a result, the cost of the substrate processing device 1 can be reduced, and the decrease in WPH can also be prevented.

In addition, the substrate processing device 1 may include a fixed cover 70 having a position fixed between the substrate W and the polishing pad 22 in a plan view. The fixed cover 70 and the swing cover 60 are located at different positions in the vertical direction Z. According to this configuration, the swing cover 60 and the fixed cover 70 function as one shielding object, and the scattered matter from the polishing pad 22 can be more reliably prevented from reaching the substrate W.

In addition, the swing cover 60 may be bent or curved in a plan view. According to this configuration, the swing cover 60 can be brought closer to the substrate W. Therefore, the scattered matter from the polishing pad 22 can be more reliably prevented from reaching the substrate W. Further, the entire swing cover 60 is easily washed by the cover washing nozzle 80. In addition, it is possible to suppress splashing back of the cover washing liquid Lc from the swing cover 60 toward the polishing pad 22.

In addition, the substrate processing device 1 may include at least one cover washing nozzle 80 that jets the cover washing liquid Lc to the swing cover 60. According to this configuration, the scattered matter adhering to the swing cover 60 can be washed.

In addition, the substrate processing device 1 may include the first cover washing nozzle 81 and the second cover washing nozzle 82. The first cover washing nozzle 81 jets the cover washing liquid Lc to the first surface 60a of the swing cover 60 facing the top ring head 24d. The second cover washing nozzle 82 jets the cover washing liquid Lc to the second surface 60b of the swing cover 60 opposite to the first surface 60a. According to this configuration, both surfaces of the swing cover 60 can be washed.

The substrate processing method according to the present embodiment includes the polishing step, the moving step, the release step, the top ring washing step, the pad washing step, the holding step, and the cover washing step. In the polishing step, the substrate W is pressed against the polishing pad 22 in a state where the turntable 23 is rotated. In the moving step, after the polishing step, the top ring head 24d is swung from the polishing position to the transfer position to move the substrate W held by the top ring head 24d. In the release step, after the moving step, the substrate W is released from the top ring head 24d at the transfer position. In the top ring washing step, after the release step, the top ring head 24d is washed.

In the pad washing step, the washing fluid F is supplied from the atomizer 26 to the polishing pad 22 to wash the polishing pad 22. In the holding step, after the release step, the new substrate W to be polished is held by the top ring head 24d. In the cover washing step, the cover washing liquid Lc is jetted from the cover washing nozzle 80 to wash the swing cover 60. The cover washing step is performed simultaneously with at least one of the release step, the top ring washing step, the pad washing step, and the holding step. According to this method, the period in which only the cover washing step is performed is eliminated, and the decrease in WPH can be prevented.

The technical scope of the present invention is not limited to the embodiment, and various changes can be made within the scope of the present invention.

For example, the cover washing nozzle 80 (the first cover washing nozzle 81 and the second cover washing nozzle 82) of the above-described embodiment is disposed at a position where both surfaces of the swing cover 60 can be washed but may be disposed at a position where only one surface can be washed. Alternatively, the substrate processing device 1 may not include the cover washing nozzle 80. In addition, the swing cover 60 of the above-described embodiment is bent or curved, but the swing cover 60 may be linear in a plan view.

In addition, the substrate processing method described in the above-described embodiment is merely an example, and the order of the steps may be changed, or steps may be added or omitted.

In addition, it is possible to appropriately replace the components in the embodiment with well-known components within the scope of the present invention, and the embodiment and the modification example may be appropriately combined.

What is claimed is:

1. A substrate processing device comprising:
a top ring including a top ring head that holds a substrate and configured to swing;
a swing cover fixed to the top ring;
a turntable to which a polishing pad is attachable and configured to rotate the polishing pad; and
an atomizer configured to supply a washing fluid to the polishing pad,
wherein when the top ring head is at a transfer position for transferring the substrate, the swing cover is positioned between the substrate and the polishing pad, and
when the top ring head is at a polishing position for polishing the substrate with the polishing pad, the swing cover does not overlap the polishing pad in a plan view.

2. The substrate processing device according to claim 1, further comprising:
a fixed cover fixed at a position between the substrate and the polishing pad in a plan view,
wherein the fixed cover and the swing cover are located at different positions in a vertical direction.

3. The substrate processing device according to claim 1,
wherein the swing cover is bent or curved in a plan view.

4. The substrate processing device according to claim 1, further comprising:
at least one cover washing nozzle configured to jet a cover washing liquid onto the swing cover.

5. The substrate processing device according to claim 1, further comprising:
a first cover washing nozzle and a second cover washing nozzle,
wherein the first cover washing nozzle is configured to jet a cover washing liquid onto a first surface of the swing cover facing the top ring head, and
the second cover washing nozzle is configured to jet the cover washing liquid onto a second surface of the swing cover opposite to the first surface.

6. A substrate processing method using the substrate processing device according to claim 4, the substrate processing method comprising:
a polishing step of pressing the substrate against the polishing pad in a state where the turntable is rotated;
a moving step of moving the substrate held by the top ring head by swinging the top ring head from the polishing position to the transfer position after the polishing step;
a release step of releasing the substrate from the top ring head at the transfer position after the moving step;
a top ring washing step of washing the top ring head after the release step;
a pad washing step of supplying the washing fluid from the atomizer to the polishing pad and washing the polishing pad;
a holding step of holding a substrate different from the substrate by the top ring head after the top ring washing step; and
a cover washing step of jetting the cover washing liquid from the cover washing nozzle and washing the swing cover,
wherein the cover washing step is performed simultaneously with at least one of the release step, the top ring washing step, the pad washing step, and the holding step.

7. The substrate processing device according to claim 2, further comprising:
at least one cover washing nozzle configured to jet a cover washing liquid onto the swing cover.

8. The substrate processing device according to claim 3, further comprising:
at least one cover washing nozzle configured to jet a cover washing liquid onto the swing cover.

9. The substrate processing device according to claim 2, further comprising:
a first cover washing nozzle and a second cover washing nozzle,
wherein the first cover washing nozzle is configured to jet a cover washing liquid onto a first surface of the swing cover facing the top ring head, and
the second cover washing nozzle is configured to jet the cover washing liquid onto a second surface of the swing cover opposite to the first surface.

10. The substrate processing device according to claim 3, further comprising:
a first cover washing nozzle and a second cover washing nozzle,
wherein the first cover washing nozzle is configured to jet a cover washing liquid onto a first surface of the swing cover facing the top ring head, and
the second cover washing nozzle is configured to jet the cover washing liquid onto a second surface of the swing cover opposite to the first surface.

11. A substrate processing method using the substrate processing device according to claim 7, the substrate processing method comprising:
a polishing step of pressing the substrate against the polishing pad in a state where the turntable is rotated;
a moving step of moving the substrate held by the top ring head by swinging the top ring head from the polishing position to the transfer position after the polishing step;
a release step of releasing the substrate from the top ring head at the transfer position after the moving step;
a top ring washing step of washing the top ring head after the release step;
a pad washing step of supplying the washing fluid from the atomizer to the polishing pad and washing the polishing pad;
a holding step of holding a substrate different from the substrate by the top ring head after the top ring washing step; and
a cover washing step of jetting the cover washing liquid from the cover washing nozzle and washing the swing cover,
wherein the cover washing step is performed simultaneously with at least one of the release step, the top ring washing step, the pad washing step, and the holding step.

12. A substrate processing method using the substrate processing device according to claim 8, the substrate processing method comprising:
a polishing step of pressing the substrate against the polishing pad in a state where the turntable is rotated;
a moving step of moving the substrate held by the top ring head by swinging the top ring head from the polishing position to the transfer position after the polishing step;
a release step of releasing the substrate from the top ring head at the transfer position after the moving step;
a top ring washing step of washing the top ring head after the release step;
a pad washing step of supplying the washing fluid from the atomizer to the polishing pad and washing the polishing pad;
a holding step of holding a substrate different from the substrate by the top ring head after the top ring washing step; and
a cover washing step of jetting the cover washing liquid from the cover washing nozzle and washing the swing cover,
wherein the cover washing step is performed simultaneously with at least one of the release step, the top ring washing step, the pad washing step, and the holding step.
